(19) United States
(12) Patent Application Publication
(10) Pub. No.: US 2008/0036024 A1
(43) Pub. Date: Feb. 14, 2008

(54) Image sensors and methods of manufacturing the same

(75) Inventors: Sung-ho Hwang, Yongin-si (KR); Duck-hyung Lee, Yongin-si (KR); Seong-sue Kim, Seoul (KR); Hong-ki Kim, Suwon-si (KR); Chang-rok Moon, Seoul (KR); Yun-ki Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/889,122

(22) Filed: Aug. 9, 2007

(30) Foreign Application Priority Data
Aug. 11, 2006 (KR) 10-2006-0076343

(51) Int. Cl. H01L 31/0232; H01L 21/00

(52) U.S. Cl. 257/432; 438/70; 257/E31.127; 257/E21.001

(57) ABSTRACT

An image sensor may include a semiconductor substrate having unit pixel regions on the semiconductor substrate; photoelectric converters formed in the unit pixel regions; interlayer insulating films covering the photoelectric converters and having opening portions formed above the photoelectric converters; a light-transmissive portion filling the opening portions; color filters formed on the light-transmissive portion; and microlenses formed on the color filters. The microlenses may include a plurality of concentric circle patterns and a plurality of arc patterns arranged around the concentric circle patterns. An arc pattern around a specific concentric circle pattern may have a same center as the specific concentric circle pattern. A method of manufacturing the image sensor may include forming the photoelectric converters; forming the interlayer insulating films; removing parts of the interlayer insulating films to form the opening portions; forming the light-transmissive portion to fill the opening portions; forming the color filters; and forming the microlenses.

### PRIORITY STATEMENT

This application claims priority from Korean Patent Application No. 10-2006-0076343, filed on Aug. 11, 2006, in the Korean Intellectual Property Office (KIPO), the entire contents of which are incorporated herein by reference.

### BACKGROUND

1. Field

Example embodiments relate to image sensors and methods of manufacturing the image sensors. Also, example embodiments relate to image sensors including improved photosensitivity and methods of manufacturing the image sensors.

2. Description of Related Art

In general, image sensors are semiconductor devices for converting an optical image into electric signals. The, image sensors are divided into two main types, that is, charge coupled device (CCD) image sensors and metal-oxide semiconductor (CMOS) image sensors.

In the CCD image sensors, complimentary metal-oxide semiconductor (MOS) capacitors are positioned adjacent to each other, and charge carriers are stored in the MOS capacitors and are transferred between the MOS capacitors. The CMOS image sensor is a switching-type device in which MOS transistors corresponding to the number of pixels are provided using a CMOS technique with a control circuit and a signal processing circuit as peripheral circuits and the MOS transistors are used to sequentially detect outputs.

In general, the CMOS image sensor includes a photoelectric converter for sensing light and converting the sensed light into electric signals, and logic elements for converting the electric signals transmitted from the photoelectric converter into data. In the CMOS image sensor, the larger the area of the photoelectric converter, for example, a photodiode becomes, the better the photosensitivity of the image sensor. Therefore, an attempt to increase a fill factor, which is the ratio of the area of the photodiode with respect to the total area of the image sensor, has been made in order to improve the photosensitivity of the image sensor.

However, due to a reduction in the size of a pixel, there is a limit to an increase in the area of the photodiode. Therefore, a microlens for changing the path of light incident on regions other than a photodiode and focusing the light on the photodiode has been introduced in order to improve the photosensitivity of the image sensor.

The microlens is formed by forming a microlens pattern on a light-receiving element of each pixel and performing a heating process on the microlens pattern to make the microlens pattern flow on the light light-receiving element.

However, when the heating process is performed during the microlens forming process, the microlenses do not completely cover the light-receiving elements, which causes dead space to be formed among the microlenses. As a result, light passing through the microlens reaches the light-receiving element, but light passing through a space among the microlenses does not reach the light-receiving element, which results in low photosensitivity of the image sensor.

Further, the related art has a problem in that reproducibility is lowered because the microlens is formed using the heating process.

### SUMMARY

Example embodiments may provide image sensors having improved photosensitivity.

Examples embodiments also may provide methods of manufacturing the image sensors.

According to example embodiments, an image sensor may include: a semiconductor substrate having unit pixel regions on the semiconductor substrate; photoelectric converters formed in the unit pixel regions; interlayer insulating films covering the photoelectric converters and having opening portions formed above the photoelectric converters; a light-transmissive portion filling the opening portions; color filters formed on the light-transmissive portion; and microlenses formed on the color filters. The microlenses may include a plurality of concentric circle patterns and a plurality of arc patterns arranged around the concentric circle patterns. An arc pattern around a specific concentric circle pattern may have a same center as the specific concentric circle pattern.

According to another example embodiment, a method of manufacturing an image sensor may include: forming photoelectric converters in unit pixel regions on a semiconductor substrate; forming interlayer insulating films that cover the photoelectric converters; removing parts of the interlayer insulating films above the photoelectric converters to form opening portions; forming a light-transmissive portion to fill the opening portions; forming color filters on the light-transmissive portion; and forming microlenses on the color filters. The microlenses may include a plurality of concentric circle patterns and a plurality of arc patterns arranged around the concentric circle patterns. An arc pattern around a specific concentric circle pattern may have a same center as the specific concentric circle pattern.

### BRIEF DESCRIPTION OF THE DRAWINGS

The above and/or other aspects and advantages will become more apparent and more readily appreciated from the following detailed description of example embodiments taken in conjunction with the accompanying drawings, in which:

FIG. 1 is a schematic circuit diagram of an active pixel sensor (APS) array of an image sensor according to an example embodiment;

FIG. 2 is a circuit diagram illustrating a unit pixel of the image sensor according to the example embodiment;

FIG. 3 is a plan view illustrating a portion of the APS array of the image sensor according to the example embodiment;

FIG. 4 is a plan view illustrating some color filters on the APS array of the image sensor according to the example embodiment;

FIG. 5 is a plan view illustrating some microlenses of the image sensor according to the example embodiment;

FIG. 6 is a cross-sectional view illustrating the image sensor according to the example embodiment, taken along the line VI-VI′ of FIG. 5;

FIG. 7 is a diagram illustrating the distribution of the intensity of light incident on a photoelectric converter through a microlens of the image sensor according to the example embodiment;

FIG. 8 is a plan view illustrating some microlenses of an image sensor according to another example embodiment; and

FIG. 9 is a cross-sectional view illustrating the image sensor according to another example embodiment, taken along the line V-V′ of FIG. 9.

### DETAILED DESCRIPTION OF EXAMPLE EMBODIMENTS

Example embodiments will now be described more fully with reference to the accompanying drawings. Embodiments, however, may be embodied in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to,” or “coupled to” another component, it may be directly on, connected to, or coupled to the other component or intervening components may be present. In contrast, when a component is referred to as being “directly on,” “directly connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the example embodiments.

Spatially relative terms, such as “beneath,” “below,” “lower,” “above,” “upper,” and the like may be used herein for ease of description to describe one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used, herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, that may be illustrated in the accompanying drawings, wherein like reference numerals may refer to the like components throughout.

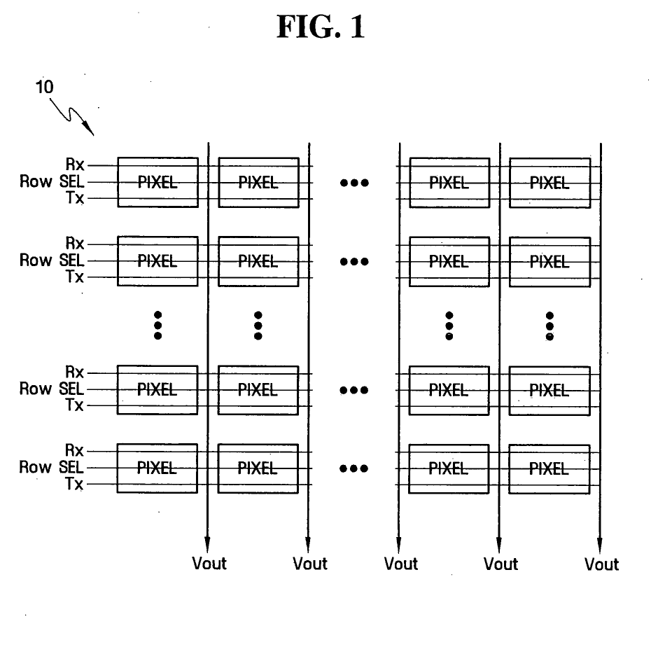

Hereinafter, image sensors according to exemplary embodiments will be described in detail with reference to FIGS. 1 to 9. In the example embodiments, a CMOS image sensor will be described as an example of an image sensor. However, the example embodiments also may be applied, for example, to a CCD image sensor.

Image sensors according to example embodiments will now be described more fully with reference to the accompanying drawings.

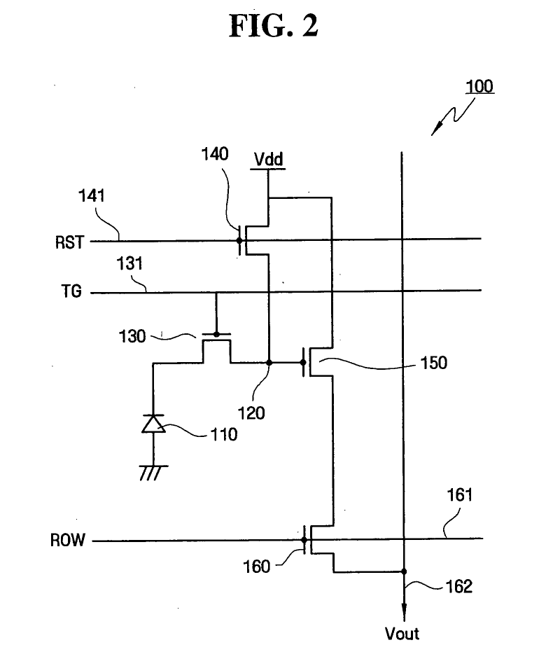

FIG. 1 is a schematic circuit diagram illustrating an APS array of an image sensor according to an example embodiment. FIG. 2 is a circuit diagram illustrating a unit pixel of an image sensor according to an example embodiment.

As shown in FIG. 1, in the image sensor, an APS array 10 for converting an optical signal into an electric signal may have unit pixel regions 100 arranged in a matrix. FIG. 2 is an equivalent circuit diagram of the unit pixel. In FIG. 2, the unit pixel region 100 may include four transistors. However, the unit pixel region 100 may include, for example, three transistors or five transistors, or it may be formed in a photogate structure that is similar to a structure composed of four transistors.

Referring to FIG. 2, the unit pixel region 100 composed of four transistors may include a photoelectric converter 110, a charge detector 120, a charge transmitter 130, a reset unit 140, an amplifier 150, and/or a selector 160.

The photoelectric converter 110 may generate charge corresponding to incident light and/or may store the charge. The photoelectric converter 110 may be, for example, a photodiode, a phototransistor, a photogate, a pinned photodiode (PPD), or a combination thereof.

The charge detector 120 may be implemented as a floating diffusion (FD) region and/or may receive the charge stored in the photoelectric converter 110. Since the charge detector 120 may have parasitic capacitance, the electric charge may be cumulatively stored in the charge detector 120. The charge detector 120 may be electrically connected to a gate of the amplifier 150 and, thus, may control the amplifier 150.

The charge transmitter 130 may transmit the charge from the photoelectric converter 110 to the charge detector 120. In general, the charge transmitter 130 may include one transistor and/or may be controlled by a charge transmission signal TG.

The reset unit 140 periodically may reset the charge detector 120. A source of the reset unit 140 may be connected to the charge detector 120. A drain of the reset unit 140 may be connected to a power supply voltage Vdd terminal. The reset unit 140 may operate in response to a reset signal RST.

The amplifier 150, in combination with a constant current source (not shown) that may be positioned outside the unit pixel region 100, may function as a source-follower buffer amplifier. A voltage varying in response to the voltage of the charge detector 120 may be output from the amplifier 150 to a vertical signal line 162. A source of the amplifier 150 may be connected to a drain of the selector 160 and/or a drain of the amplifier 150 may be connected to the power supply voltage Vdd terminal.

The selector 160 may select each row of the unit pixel regions 100 to be read. The selector 160 may operate in response to a pixel selection signal ROW, and/or a source of the selector 160 may be connected to the vertical signal line 162.

In addition, driving signal lines 131, 141, and/or 161 of the charge transmitter 130, the reset unit 140, and/or the selector 160 may extend in a row direction (horizontal direction) so that the unit pixel regions 100 belonging to the same row are simultaneously driven.

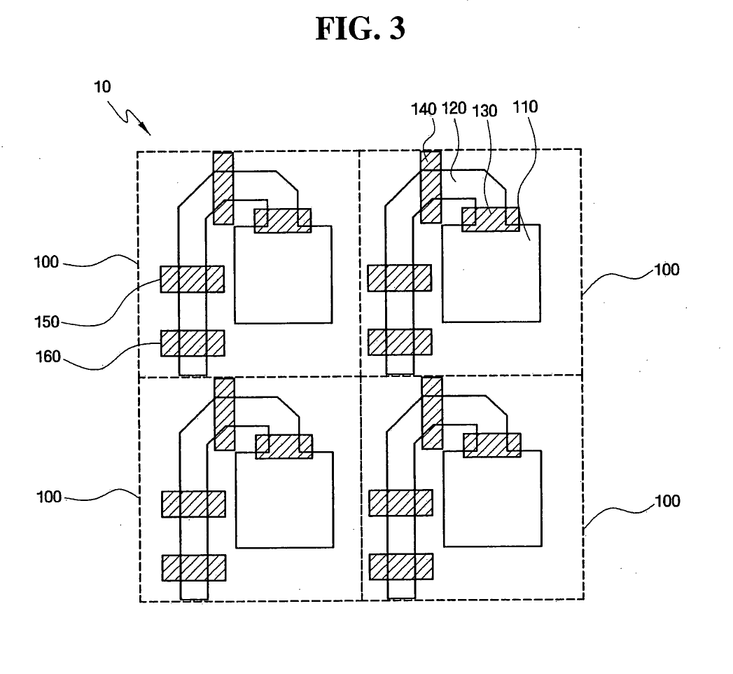

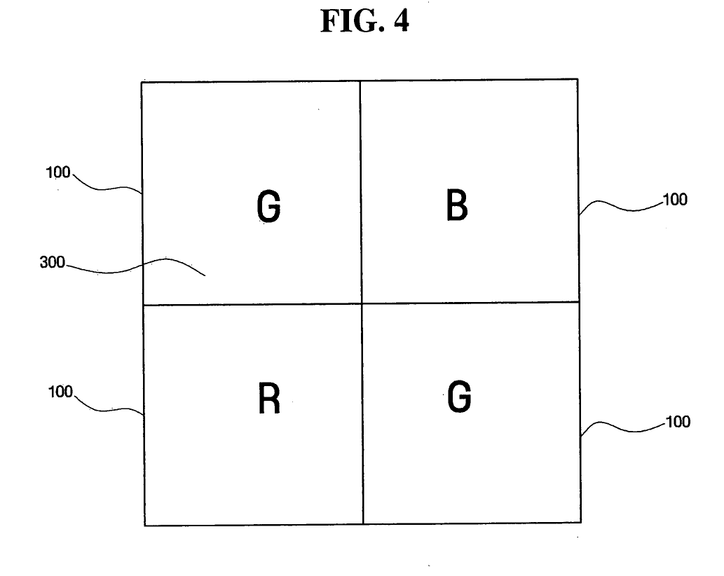

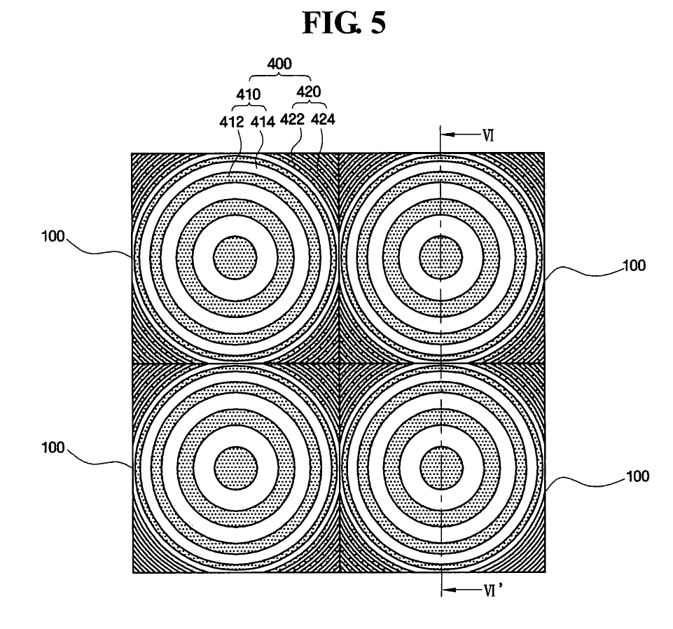

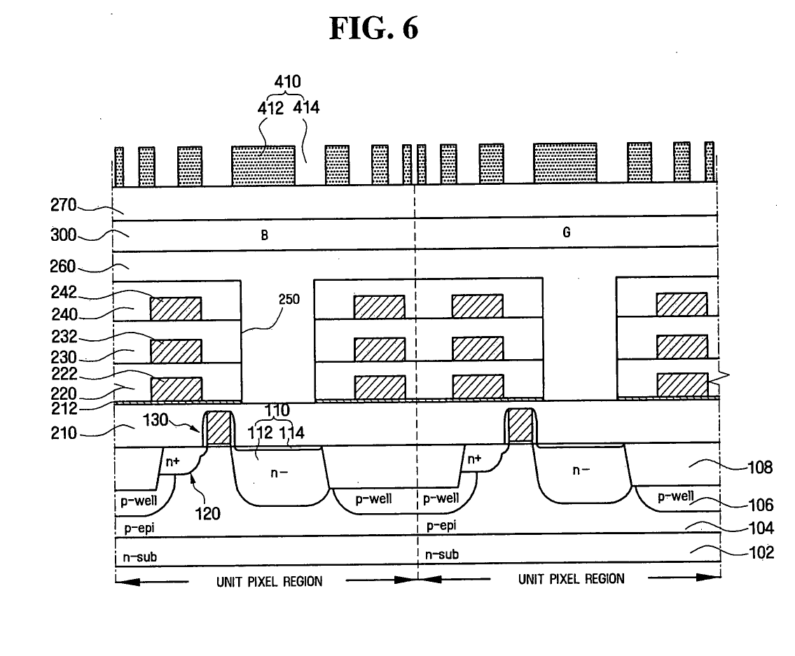

FIG. 3 is a plan view illustrating a portion of an APS array of an image sensor according to an example embodiment. FIG. 4 is a plan view illustrating a portion of a color filter formed on an APS array of an image sensor according to an example embodiment. FIG. 5 is a plan view illustrating some microlenses of an image sensor according to an example embodiment. FIG. 6 is a cross-sectional view of the image sensor according to the example embodiment, taken along the line VI-VI′ of FIG. 5.

As shown in FIGS. 3 and 6, since the unit pixel regions 100 may be arranged in a matrix, the APS array 10 may divide the semiconductor substrate into rectangular unit pixel regions 100. The photoelectric converter 110 may be positioned, for example, at the center of each of the unit pixel regions 100, and/or the charge detector 120, the charge transmitter 130, the reset unit 140, the amplifier 150, and/or the selector 160 may be positioned around the photoelectric converter 110 in each unit pixel region 100.

More specifically, in an image sensor according to an example embodiment, a p-type epitaxial layer 104 may be formed on an n-type silicon substrate 102, a p-well 106, and/or an n-well (not shown), for respectively forming positive-channel metal-oxide semiconductors (PMOS) and/or negative-channel metal-oxide semiconductors (NMOS) in the p-type epitaxial layer 104. A device isolation film 108, for isolating an active region from a field region, may be formed in the p-type epitaxial layer 104. The active region is not limited to that shown in FIG. 3, but may have many other shapes.

The photoelectric converter 110 for storing charges generated by absorption of light energy may be formed in the active region defined by the device isolation film 108. The photoelectric converter 110 may include an n-type photodiode 112 and/or a p+ pinning layer 114. The n-type photodiode 112 may be formed deep in the p-type epitaxial layer 104, and the p+ pinning layer 114 may be formed on the n-type photodiode 112 with a small thickness. Therefore, the photoelectric converter 110 may have a pnp junction structure that includes the p-type epitaxial layer 104, the n-type photodiode 112, and/or the p+ pinning layer 114.

The p+ pinning layer 114 formed on the n-type photodiode 112 with a small thickness may prevent a dark current from being generated due to surface damage of the n-type photodiode 112. More specifically, in the image sensor, the surface damage of the photoelectric converter 110 may cause the dark current. The surface damage of the photoelectric converter 110 may be mainly caused by dangling silicon bonds, or it may be caused by defects related to etching stress during a manufacturing process, for example. Therefore, the n-type photodiode 112 may be deeply formed in the p-type epitaxial layer 104 and/or the p+ pinning layer 114 may be formed on the n-type photodiode 112. Then, among electron-hole pairs thermally generated from the surface of the p-type epitaxial layer 104, positive charges may be diffused to a grounded substrate through the p+ pinning layer 114, and/or negative charges may be recombined with the positive charges to be removed while the p+ pinning layer 114 is formed.

The charge detector 120 may be formed in the p-type epitaxial layer 104 so as to be separated from the photoelectric converter 110. The charge detector 120 may be formed in a lightly doped drain (LDD) structure obtained by implanting n-type impurities at low concentration and/or n-type impurities at high concentration.

The charge transmitter 130 for transmitting the photocharge stored in the photoelectric converter 110 to the charge detector 120 may be arranged on the p-type epitaxial layer 104 between the photoelectric converter 110 and the charge detector 120.

A first interlayer insulating film 210 may be formed on the photoelectric converter 110, the charge detector 120, the charge transmitter 130, the reset unit 140, the amplifier 150, and/or the selector 160 so as to cover the entire surface of the n-type silicon substrate 102. Contacts (not shown) connected to the charge detector 120, the reset unit 140, the amplifier 150, and/or the selector 160 may be formed in the first interlayer insulating film 210.

A plurality of interlayer insulating films 220, 230, and/or 240 may be formed on the first interlayer insulating film 210, and an etch stop film 212 may be formed between the first interlayer insulating film 210 and the second interlayer insulating film 220. In addition, metal wiring lines 222, 232, and/or 242 may be formed in the interlayer insulating films 220, 230, and/or 240, respectively. In this case, the metal wiring lines 222, 232, and/or 242 may be disposed in regions other than the upper part of the photoelectric converter 110. An opening portion 250 may be formed in the interlayer insulating films 220, 230, and/or 240 at a position corresponding, for example, to the photoelectric converter 110.

A light-transmissive portion 260 may be formed on the interlayer insulating films 220, 230, and/or 240, so as to fill the opening portion 250. The light-transmissive portion 260 may be formed flat on the opening portion 250 and/or the interlayer insulating films 220, 230, and/or 240. The light-transmissive portion 260 may be formed of a material transmitting light incident on the photoelectric converter 110, such as a thermosetting resin.

Color filters 300 may be arranged on the light-transmissive portion 260. Referring to FIG. 4, the color filter 300 may be arranged for each unit pixel region 100 on the APS array 10 having the unit pixel regions 100 arranged in a matrix. The color filters 300 may transmit specific color light components to reach the photoelectric converter 110 of the semiconductor substrate in order to obtain a high-quality image. The color filters 300 may be arranged in a Bayer-type color filter array in which red (R), green (G), and blue (B) color filters are arranged in the Bayer-type array. In the Bayer-type color filter array, the number of green color filters 300 may be half the total number of color filters due to the fact that human eye is more sensitive to green requiring high accuracy than other colors. However, the arrangement of the color filters 300 is not limited to the Bayer-type array.

As shown in FIGS. 5 and 6, a microlens 400 may be arranged above the color filter 300 in each unit pixel region 100. The microlens 400 may change the path of light incident on regions, for example, other than the upper part of the photoelectric converter 110 to concentrate light on the photoelectric converter 110.

The microlens 400 formed in each unit pixel region 100 may use the principle of the Fresnel zone plate lens serving as a convex lens. That is, the microlens 400 may be disposed above the photoelectric converter 110 of the semiconductor substrate, and/or may include concentric circle pattern or patterns 410 and/or arc patterns or patterns 420 positioned around the concentric circle pattern or patterns 410. The arc pattern or patterns 420 and the concentric circle pattern or patterns 410 may have the same center, and/or the center of the concentric circle pattern or patterns 410 may be laid on a vertical line passing through the center of the photoelectric converter 110.

In the microlens 400 including the concentric circle pattern or patterns 410 and/or the arc pattern or patterns 420, patterns having different refractive indexes may be alternately arranged, and/or may have different widths. More specifically, the concentric circle pattern or patterns 410 may include an opaque pattern or patterns 412 and/or a transparent pattern or patterns 414, and the arc pattern or patterns 420 may include an opaque pattern or patterns 422 and/or a transparent pattern or patterns 424. The opaque patterns 412 and 422 and/or the transparent patterns 414 and 424 may be alternately arranged.

In this case, the opaque pattern or patterns 412 and the opaque pattern or patterns 422 may have the same thickness, and the widths of the concentric circle pattern or patterns 410 and/or the arc pattern or patterns 420 may become larger as the concentric circular pattern or patterns 410 and/or the arc pattern or patterns 420 are closer to the center of the unit pixel region 100. The opaque pattern or patterns 412 separated from each other may have the same area.

That is, in the microlens 400, the concentric circle pattern or patterns 410 may be disposed in the rectangular unit pixel region 100, and/or the arc pattern or patterns 420 may be disposed in regions of the unit pixel region 100 other than the region in which the concentric circle pattern or patterns 410 are arranged. Therefore, when a circular microlens 400 is formed in each unit pixel region 100, it may be possible to prevent dead space among the microlenses 400.

A planarizing film 270, which is called an over-coating layer (OCL), may be formed between the color filter 300 and the microlens 400. The planarizing film 270 may be formed, for example, of a thermosetting resin.

As a result, the microlens 400 may be arranged on the planarizing film 270 to allow the planarizing film 270 to be exposed through the transparent patterns of the concentric circle pattern or patterns 410 and the arc pattern or patterns 420.

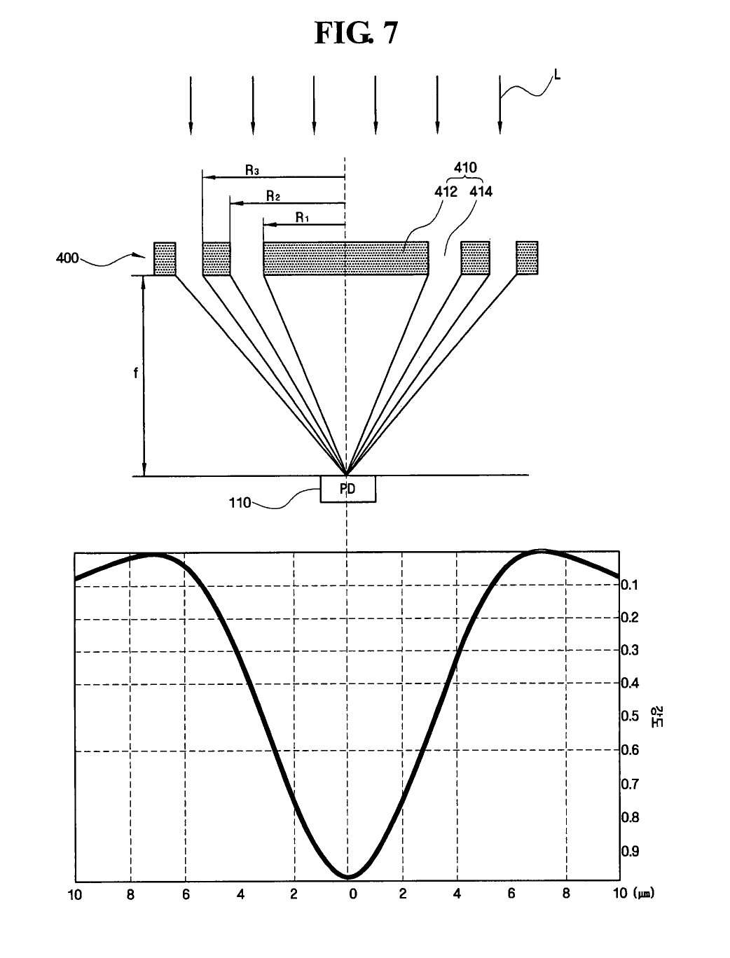

The widths of the concentric circle pattern or patterns 410 and/or the arc pattern or patterns 420 of the microlens 400 and the light-collecting ability thereof will be described in detail below with reference to FIG. 7. FIG. 7 is a diagram illustrating the distribution of the intensity of light incident on a photoelectric converter through a microlens of an image sensor according to an example embodiment.

In the microlens 400 including the concentric circle pattern or patterns 410 and the arc pattern or patterns 420 that may have the same center, the opaque pattern or patterns 412 and the transparent pattern or patterns 414 may be alternately arranged, and/or light may be incident on the microlens 400. Referring to FIG. 7, when the distance from the bottom of the microlens 400 to the photoelectric converter 110 is “l”, the outer radii of the opaque pattern or patterns 412 may be R₁, R₂, . . . , Rₙ. The outer radii Rₙ may have the following relationship: Rₙ²=n²·λ²/m²+2n·λ/m. In this case, R represents the outer radius of a pattern or patterns in micrometers (μm), n represents a natural number (n=1, 2, 3, . . . ), λ represents the wavelength of incident light L in nanometers (nm), and m also represents a natural number (m=1, 2, 3, . . . ). In addition or in the alternative, the outer radii Rₙ may have the following relationship: Rₙ²=nfλ+n²·λ²/4. In this case, R represents the outer radius of a pattern or patterns in micrometers (μm), n represents a natural number (n=1, 2, 3, . . . ), f represents the focal distance in micrometers (μm), and λ represents the wavelength of incident light L in nanometers (nm). The term n²·λ²/4 represents a correction for spherical aberration and may be omitted when nλ<<f. The width of the nth zone may be Rₙ-Rₙ₋₁.

That is, when the opaque pattern or patterns 412 having the outer radii R₁, R₂, . . . , Rₙ are formed and the transparent pattern or patterns 414 are formed between the opaque pattern or patterns 412, the phase of incident light L may be delayed in the opaque pattern or patterns 412 because the opaque pattern or patterns 412 and/or the transparent pattern or patterns 414 may have different refractive indices. Therefore, the constructive interference of the incident light L passing through the microlens 400 may occur on the surface of the photoelectric converter 110, and/or the incident light L may be focused on the photoelectric converter 110.

It may be possible to ascertain the operation of the microlens 400 through a light-intensity profile represented in a graph. The graph shown in FIG. 7 indicates the intensity of light when the size of a pixel is approximately 8 μm, the distance “l” from the bottom of the microlens 400 to the photoelectric converter 110 is approximately 15 μm, and the wavelength of light is approximately 700 nm. The graph shown in FIG. 7 shows that the microlens 400 according to an example embodiment may function as a filter that may improve the sensitivity to a specific wavelength, but also may lower the sensitivity to other wavelengths.

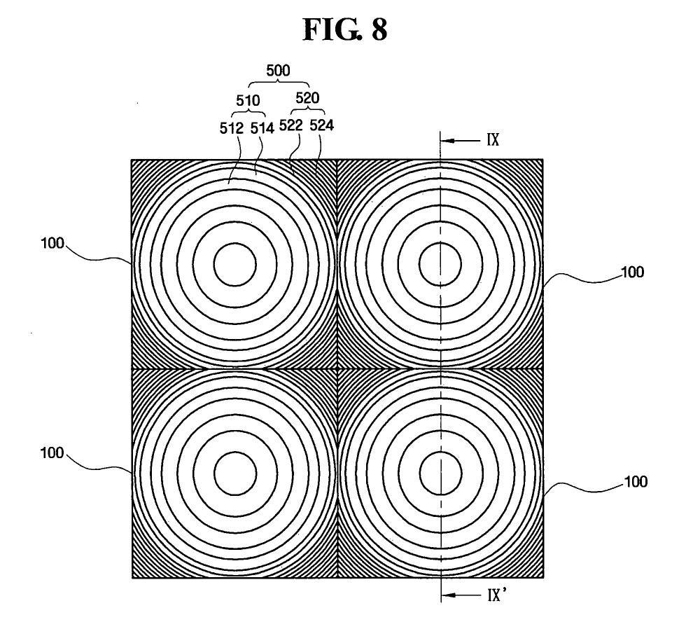

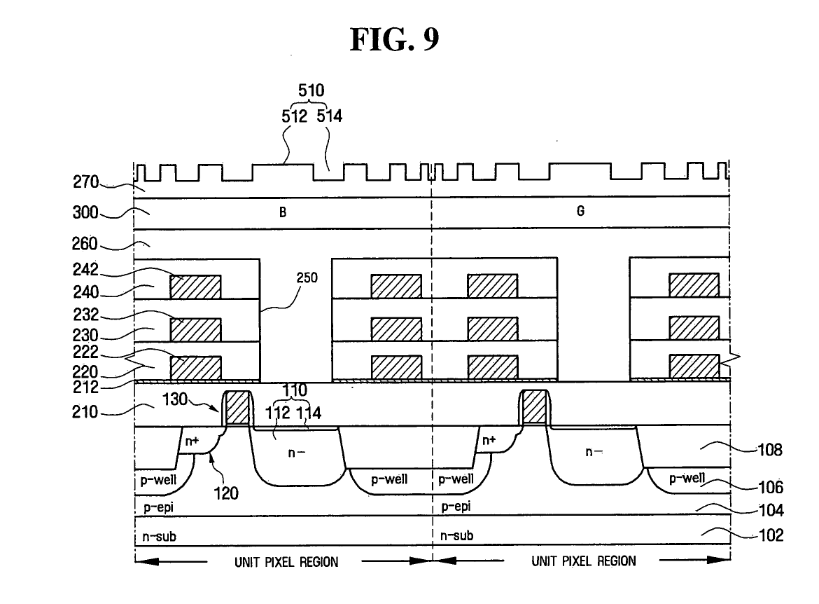

Next, an image sensor according to another example embodiment will be described below with reference to FIGS. 8 and 9. In this embodiment, the same components as those shown in FIGS. 5 and 6 have the same reference numerals, and a detailed description thereof will be omitted.

FIG. 8 is a plan view illustrating some microlenses of an image sensor according to the example embodiment that are formed on the color filters shown in FIG. 4. FIG. 9 is a cross-sectional view of the image sensor according to the example embodiment, taken along the line IX-IX′ of FIG. 8.

As shown in FIGS. 8 and 9, the planarizing film 270 made, for example, of a thermosetting resin may be formed on color filters 300. Then, microlenses 500 may be formed on parts of the planarizing film 270.

More specifically, a plurality of concentric circle pattern or patterns 510 and/or arc pattern or patterns 520 having the same center may be formed on the upper surface of the planarizing film 270. The center of the concentric circle pattern or patterns 510 and/or the arc pattern or patterns 520 may be laid on a vertical line passing through the center of the photoelectric converter 110.

The concentric circle pattern or patterns 510 and/or the arc pattern or patterns 520 may include convex pattern or patterns 512 and 522 and/or concave pattern or patterns 514 and 524. The convex pattern or patterns 512 and 522 and/or the concave pattern or patterns 514 and 524 may be alternately arranged. The concentric circle pattern or patterns 510 and/or the arc pattern or patterns 520 may have different widths. The widths of the concentric circle pattern or patterns 510 and/or the arc pattern or patterns 520 may become larger as the concentric circle pattern or patterns 510 and/or the arc pattern or patterns 520 are closer to the edge of the microlens 500.

In the concentric circle pattern or patterns 510 and/or the arc pattern or patterns 520, including the convex pattern or patterns 512 and 522 and/or the concave pattern or patterns 514 and 524 alternately arranged, the convex pattern or patterns 512 and 522 may have the outer radii Rₙ, as described above. The outer radii Rₙ may have the following relationship: Rₙ²=n²·λ²/m²+2n·λ/m. In this case, R represents the outer radius of a pattern or patterns in micrometers (μm), n represents a natural number (n=1, 2, 3, . . . ), λ represents the wavelength of incident light L in nanometers (nm), and m also represents a natural number (m=1, 2, 3, . . . ). In addition or in the alternative, the outer radii Rₙ may have the following relationship: Rₙ²=nfλ+n²·λ²/4. In this case, R represents the outer radius of a pattern or patterns in micrometers (μm), n represents a natural number (n=1, 2, 3, . . . ), f represents the focal distance in micrometers (μm), and λ represents the wavelength of incident light L in nanometers (nm). The term n²·λ²/4 represents a correction for spherical aberration and may be omitted when nλ<<f. The width of the nth zone may be RₙRₙ₋₁.

As described above, the microlens 500 formed in a portion of the planarizing film 270 may include the convex pattern or patterns 512 and 522 and/or the concave pattern or patterns 514 and 524. Therefore, when light is incident on the photoelectric converter 110, the phase of the light may be changed. Thus, constructive interference of the incident light L may occur on the surface of the photoelectric converter 110, and/or the light may be focused on the photoelectric converter 110.

Next, a method of manufacturing an image sensor according to an example embodiment will be described in detail below with reference to FIGS. 5, 6, 8, and 9.

First, a semiconductor substrate may be prepared. An epitaxial substrate may be used as the semiconductor substrate. An epitaxial substrate having an n-type substrate 102 and/or a p-type epitaxial layer 104 formed on the n-type substrate 102 may be used to prevent crosstalk of an image element and/or to optimize characteristics of the image element.

Then, a p-well 106 and/or an n-well may be formed in the p-type epitaxial layer 104. That is, an ion implantation mask for exposing a region in which the p-well 106 will be formed may be formed, and p-type impurities, such as boron, may be implanted to form the p-well 106. Then, the ion implantation mask may be removed, and an ion implantation mask for exposing a region in which the n-well (not shown) will be formed may be formed. Subsequently, n-type impurities, such as phosphorus, may be implanted to form the n-well (not shown).

The device isolation film 108 may be formed in the p-type epitaxial layer 104 of the epitaxial semiconductor substrate using the APS layout shown in FIG. 3 to define the active regions in which the photoelectric converter 110 and/or the charge detector 120 will be formed. The device isolation film 108 may be formed, for example, by a local oxidation of silicon (LOCOS) process or a shallow trench isolation (STI) process.

Then, a gate insulating film and/or a conductive film for a gate may be sequentially formed on the p-type epitaxial layer 104, and the films may be patterned to form gate patterns (see reference numerals 130, 140, 150, and 160 in FIG. 3). The gate insulating film may be formed, for example, using one or more of SiO₂, SiOₙ, SiN, Al₂O₃, Si₃N₄, GeₓO_{y}N_{z}, GeₓSi_{y}O_{z}, and a high-dielectric material. The high-dielectric material may be formed using one or more of HfO₂, ZrO₂, Al₂O₃, Ta₂O₅, hafnium silicate, and zirconium silicate by, for example, an atomic layer deposition method. In addition, the gate insulating film may be formed in a laminated structure of a plurality of layers formed of at least two of the above-mentioned materials. The gate insulating film may be formed with a thickness greater than or equal to about 5 Å and less than or equal to about 100 Å. The conductive film for a gate may be formed, for example, of a conductive polysilicon film, a metal film (such as, for example, a W, Pt, or Al film), a metal nitride film (such as, for example, a TiN film), a metal silicide film made of refractory metal (such as, for example, Co, Ni, Ti, Hf, or Pt), a laminated film of the conductive polysilicon film and the metal silicide film, or a laminated film of the conductive polysilicon film and a metal film. In addition, gate spacers may be formed at one or both sides of each of the gate patterns (see reference numerals 130, 140, 150, and 160 in FIG. 3).

Then, the photoelectric converter 110, including the n-type photodiode 112 and/or the p+ pinning layer 114, may be formed on one side of the gate pattern of the charge transmitter 130. More specifically, an ion implantation mask for exposing the region in which the photoelectric converter 110 will be formed may be formed, and/or n-type impurities may be deeply implanted into the p-type epitaxial layer 104 to form the n-type photodiode 112. In this case, the n-type photodiode 112 may be inclined at an angle greater than or equal to 0° and less than or equal to about 15° with respect the gate pattern of the charge transmitter 130. Therefore, the n-type photodiode 112 may be formed so as to at least partially overlap a transfer gate pattern.

Then, p-type impurities may be shallowly implanted into the n-type photodiode 112 to form the p+ pinning layer 114. In this case, the p-type impurities may be implanted at an angle greater than 0° with respect to the device isolation film 108. The p+ pinning layer 114 formed in this way may reduce electron-hole pairs (EHPs) thermally generated from the p-type epitaxial layer 104 and/or may prevent dark current.

The charge detector 120 may be formed in the p-type epitaxial layer 104 so as to be separated from the photoelectric converter 110. In this case, the charge detector may be formed by implanting n-type impurities, and/or it may be formed in a LDD structure.

In this way, the APS array 10 of the image sensor, including the photoelectric converter 110, the charge detector 120, the charge transmitter 130, the reset unit 140, the amplifier 150, and/or the selector 160 may be completed.

The first interlayer insulating film 210 may be formed on the entire surface of the substrate having the APS array 10 formed thereon, and/or the etch stop film 212 may be formed on the first interlayer insulating film 210. The first interlayer insulating film 210 may be formed of a transparent insulating material capable of transmitting incident light. For example, any of the following materials may be used as the first interlayer insulating film 210: high density plasma (HDP), tonen silazene (TOSZ), spin on glass (SOG), and undoped silica glass (USG). A silicon nitride film may be used, for example, as the etch stop film 212.

The metal wiring lines 222, 232, and/or 242 and/or the interlayer insulating films 220, 230, and/or 240 may be sequentially formed on the etch stop film 212. In this way, the metal wiring lines 222, 232, and/or 242 and/or the interlayer insulating films 220, 230, and/or 240 may be formed. Here, in the APS array 10, the arrangement of the metal wiring lines 222, 232, and/or 242 for the electrical routing and/or light shielding of elements may be changed in various manners.

The interlayer insulating films 220, 230, and/or 240 may be partially etched until the etch stop film 212 is exposed, thereby forming the opening portion 250 for allowing the first interlayer insulating film 210 formed on the photoelectric converter 110 to be exposed. The opening portion 250 may prevent the transmittance of light from being lowered due to the refraction/reflection of light incident on the photoelectric converter 110 from the third interlayer insulating film 230 and/or the etch stop film 212 formed above the photoelectric converter 110 and, thus, may prevent crosstalk. That is, the opening portion 250 may improve the transmittance of light.

Then, a resin, for example, that transmits incident light may fill the opening portion 250 to form the light-transmissive portion 260 having a flat upper surface. The color filters 300 may be formed on the light-transmissive portion 260 in each unit pixel region 100. In this case, as shown in FIG. 4, the red (R) color filter(s), the green (G) color filter(s), and/or the blue (B) color filter(s) may be arranged in the Bayer-type array. Then, the planarizing film 270 made, for example, of a resin that transmits light may be formed on the color filters 300.

The microlens 400 or 500 having the concentric circle pattern or patterns 410 or 510 and/or the arc pattern or patterns 420 or 520 may be formed on the planarizing film 270 in each unit pixel region 100.

As shown in FIG. 6, in the microlens 400, an opaque film having a refractive index different from that of the planarizing film 270 may be formed on the planarizing film 270. The opaque film may be formed, for example, of a silicon nitride (Si₃N₄), a titanium nitride (TiN), and/or a magnesium oxide (MgO₂).

The opaque film may be patterned to form the concentric circle pattern or patterns 410 and/or the arc pattern or patterns 420 arranged around the concentric pattern or patterns 410 in each unit pixel region 100 so that the concentric circle pattern or patterns 410 and/or the arc pattern or patterns 420 may have the same center. The center of the concentric circle pattern or patterns 410 and/or the arc pattern or patterns 420 may be positioned above the center of the photoelectric converter 110.

In this way, the concentric circle pattern or patterns 410 and/or the arc pattern or patterns 420 composed of the opaque film may be formed, and/or the concentric circle pattern or patterns 410 and/or the arc pattern or patterns 420 may be obtained by removing the opaque film. That is, the transparent pattern or patterns 414 and 424 may expose the planarizing film 270. The microlens 400 may be formed so that, as the concentric circle pattern or patterns 410 and the arc pattern or patterns 420 are closer to the center of the microlens 400, the widths thereof are larger.

The microlens 500 may be formed as shown in FIG. 9. Referring to FIG. 9, the microlens 500 may be formed in a part of the planarizing film 270. That is, the planarizing film 270 may be formed on the color filters 300, and/or the planarizing film 270 may be patterned to form the concentric circle pattern or patterns 510 and/or the arc pattern or patterns 520 in each unit pixel region 100. The arc pattern or patterns 520 may be arranged around the concentric circle pattern or patterns 510 in each unit pixel region 100.

In the microlens 500 formed by patterning the planarizing film 270, the concentric circle pattern or patterns 510 and/or the arc pattern or patterns 520 may include the convex pattern or patterns 512 and 522 and/or the concave pattern or patterns 514 and 524. The convex pattern or patterns 512 and 522 and/or the concave pattern or patterns 514 and 524 may be alternately arranged, which may cause the phase of light incident thereon to be changed.

When the concentric circle pattern or patterns 410 and 510 and/or the arc pattern or patterns 420 and 520 may be formed by the above-mentioned methods, the widths of the pattern or patterns may be defined by the wavelength of light and/or the distance from the microlens 400 or 500 to the photoelectric converter 110. Therefore, when the microlens 400 or 500 are repeatedly formed, it may be possible to form uniform microlenses.

As described above, according to the image sensors and the methods of manufacturing the image sensors, when a circular microlens is formed in each unit pixel region, it may be possible to prevent dead space among the microlenses and, thus, to improve the sensitivity of an image sensor. In addition, the concentric circle pattern or patterns and/or the arc pattern or patterns forming the microlens may be regularly formed, which may make it possible to improve reproducibility when the microlenses are repeatedly formed.

Further, the microlenses according to the above-described example embodiments may serve as filters capable of improving the sensitivity to a specific wavelength and/or lowering the sensitivity to other wavelengths.

While example embodiments have been particularly shown and described, it will be understood by those of ordinary skill in the art that various changes in form and details may be made therein without departing from the spirit and scope of the present invention as defined by the following claims.

What is claimed is:

1. An image sensor, comprising:
a semiconductor substrate having unit pixel regions on the semiconductor substrate;
photoelectric converters formed in the unit pixel regions;
interlayer insulating films covering the photoelectric converters and having opening portions formed above the photoelectric converters;
a light-transmissive portion filling the opening portions;
color filters formed on the light-transmissive portion; and
microlenses formed on the color filters;
wherein the microlenses comprise:
a plurality of concentric circle patterns; and
a plurality of arc patterns arranged around the concentric circle patterns; and
wherein an arc pattern around a specific concentric circle pattern has a same center as the specific concentric circle pattern.

2. The image sensor of claim 1, wherein the unit pixel regions comprise one or more rectangular shapes.

3. The image sensor of claim 1, further comprising:
a planarizing film formed between the color filters and the microlenses.

4. The image sensor of claim 1, wherein the center of the arc pattern around the specific concentric circle pattern lies on a vertical line passing through a center of a respective photoelectric converter.

5. The image sensor of claim 1, wherein the concentric circle patterns and the arc patterns have different refractive indices, and
wherein the concentric circle patterns and the arc patterns are arranged so that the different refractive indices alternate.

6. The image sensor of claim 1, wherein the concentric circle patterns and the arc patterns have different widths, and
wherein the closer the concentric circle patterns and the arc patterns are to centers of respective microlenses, the larger are the widths of the concentric circle patterns and the arc patterns.

7. The image sensor of claim 1, wherein the concentric circle patterns have a same area.

8. The image sensor of claim 1, wherein the concentric circle patterns and the arc patterns comprise opaque patterns and transparent patterns, alternately arranged.

9. The image sensor of claim 3, wherein the concentric circle patterns and the arc patterns comprise opaque patterns and transparent patterns, alternately arranged.

10. The image sensor of claim 9, wherein the transparent patterns expose the planarizing film.

11. The image sensor of claim 1, wherein the concentric circle patterns and the arc patterns comprise convex patterns and concave patterns, alternately arranged.

12. A method of manufacturing an image sensor, the method comprising:
forming photoelectric converters in unit pixel regions on a semiconductor substrate;
forming interlayer insulating films that cover the photoelectric converters;
removing parts of the interlayer insulating films above the photoelectric converters to form opening portions;
forming a light-transmissive portion to fill the opening portions;
forming color filters on the light-transmissive portion; and
forming microlenses on the color filters, the microlenses including a plurality of concentric circle patterns and a plurality of arc patterns arranged around the concentric circle patterns, wherein an arc pattern around a specific concentric circle pattern has a same center as the specific concentric circle pattern.

13. The method of claim 12, further comprising:
forming a planarizing film on the color filters before forming the microlenses.

14. The method of claim 12, further comprising:
forming a planarizing film between the color filters and the microlenses.

15. The method of claim 12, wherein the forming of the microlenses comprises:
laying the center of the arc pattern around the specific concentric circle pattern on a vertical line passing through a center of a respective photoelectric converter.

16. The method of claim 12, wherein the forming of the microlenses comprises:
forming the concentric circle patterns and the arc patterns with different refractive indices; and
arranging the concentric circle patterns and the arc patterns so that the different refractive indices alternate.

17. The method of claim 13, wherein the forming of the microlenses comprises:
forming an opaque film on the planarizing film; and
patterning the opaque film to form the concentric circle patterns and the arc patterns so that the concentric circle patterns and the arc patterns comprise opaque patterns and transparent patterns, alternately arranged.

18. The method of claim 17, wherein the transparent patterns expose the planarizing film.

19. The method of claim 14, wherein the forming of the microlenses comprises:
forming an opaque film on the planarizing film; and
patterning the opaque film to form the concentric circle patterns and the arc patterns so that the concentric circle patterns and the arc patterns comprise opaque patterns and transparent patterns, alternately arranged.

20. The method of claim 19, wherein the transparent patterns expose the planarizing film.

21. The method of claim 12, wherein the concentric circle patterns and the arc patterns have different widths, and
wherein the closer the concentric circle patterns and the arc patterns are to centers of respective microlenses, the larger are the widths of the concentric circle patterns and the arc patterns.

22. The method of claim 13, wherein the forming of the microlenses comprises:
patterning the planarizing film to form the concentric circle patterns and the arc patterns so that the concentric circle patterns and the arc patterns comprise convex patterns and concave patterns, alternately arranged.

23. The method of claim 22, wherein the convex patterns and the concave patterns have different widths, and
wherein the closer the convex patterns and the concave patterns are to centers of respective microlenses, the larger are the widths of the convex patterns and the concave patterns.

24. The method of claim 14, wherein the forming of the microlenses comprises:
patterning the planarizing film to form the concentric circle patterns and the arc patterns so that the concentric circle patterns and the arc patterns comprise convex patterns and concave patterns, alternately arranged.

25. The method of claim 24, wherein the convex patterns and the concave patterns have different widths, and
wherein the closer the convex patterns and the concave patterns are to centers of respective microlenses, the larger are the widths of the convex patterns and the concave patterns.
